(19) United States
(12) Patent Application Publication
(10) Pub. No.: US 2025/0201605 A1
(43) Pub. Date: Jun. 19, 2025

(54) ASSEMBLY AND METHOD FOR PREVENTING WARPAGE IN A SEMICONDUCTOR PACKAGE

(71) Applicant: Intel Corporation, Santa Clara, CA (US)

(72) Inventors: Sonja Koller, Lappersdorf (DE); Pouya Talebbeydokhti, Mesa, AZ (US); Vishnu Prasad, Munich (DE); Stefan Reif, Munich (DE); Carlton Hanna, Santa Clara, CA (US); Thomas Wagner, Regelsbach (DE)

(21) Appl. No.: 18/539,349

(22) Filed: Dec. 14, 2023

(51) Int. Cl. H01L 21/67; H01L 21/02; H01L 21/48; H01L 21/687; H01L 21/768; H01L 21/8234

(52) U.S. Cl. CPC H01L 21/67288; H01L 21/02422; H01L 21/4803; H01L 21/68714; H01L 21/76837; H01L 21/76894; H10D 84/0128; H10D 84/038

(57) ABSTRACT

The present disclosure relates to an assembly for preventing warpage in a semiconductor package. The assembly may include a semiconductor package substrate including one or more channels arranged longitudinally in an inner core layer of the semiconductor package substrate. The assembly may further include a mount assembly including one or more mounts operable to be insertable into corresponding channels of the semiconductor package substrate.

### BACKGROUND

Wafer-level semiconductor packaging has gained traction in industry to achieve advanced packaging technologies like silicon disaggregation in 2.3D, 2.5D and 3D approaches. Wafers can be limited in area due to their fixed diameter of maximum of 300 mm and round shape. Panel-level process is beginning to get traction in industry to provide larger size of more than 500 mm and square area to increase area for utilization, process efficiency, and cost. However, one challenge for panel-level processing is that due to its larger size, the warpage or flatness across the full panel is greater than that of the smaller wafers when processed under the same conditions. This can contribute to process issues across the entire panel. In other words, warpage at assembly has not been an issue for smaller wafer formats. However, larger panel formats are prone to warpage at assembly. Therefore, controlling this warpage would provide significant improvement to processing at the panel level.

Further, for the larger panel formats, through-plane paths (i.e., from a device top side to bottom side) for heat extraction and power supply come with larger distances, causing higher temperatures and higher losses.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A shows a perspective view of an assembly prior to an assembling of a panel and an assembly mount according to an aspect of the present disclosure;

FIG. 1B shows a perspective view of the assembly of FIG. 1A, during and/or after assembling of the panel and the assembly mount according to an aspect of the present disclosure;

FIG. 2 shows a plan view (left) and a side view (right) of an assembly of FIG. 1A, during and/or after assembling of a panel and an assembly mount according to an aspect of the present disclosure;

FIGS. 3A-3D show the formation of channels in a panel according to an aspect of the present disclosure;

FIG. 4 shows a perspective view (left) and a cross-sectional view (right) of an innermost core layer according to an aspect of the present disclosure;

FIG. 5 shows a perspective view (left) and a cross-sectional view (right) of an innermost core layer having partially filled channels according to an aspect of the present disclosure;

FIG. 6 shows a perspective view (left) and a cross-sectional view (right) of an innermost core layer having filled channels according to another aspect of the present disclosure;

FIG. 7 shows a side electrical and/or thermal connections between conductive structures in a panel according to an aspect of the present disclosure; and

FIG. 8 shows a flow chart illustrating a method for preventing warpage in a panel according to an aspect of the present disclosure.

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

The present disclosure may attempt to address warpage and assembly issues and to improve thermal dissipation and power delivery systems in interposers and 3D architectures.

In one aspect, the present disclosure relates to an assembly for preventing warpage in a semiconductor package. The assembly may include a semiconductor package substrate including one or more channels arranged longitudinally in an inner core layer of the semiconductor package substrate. The assembly may further include a mount assembly including one or more mounts operable to be insertable into corresponding channels of the semiconductor package substrate.

The present disclosure also relates to a semiconductor package substrate. The semiconductor package substrate may include an inner core layer including one or more channels arranged longitudinally in the inner core layer. Each of the one or more channels may include an opening extending from one side of the inner core layer. The semiconductor package substrate may further include two outer layers arranged to sandwich the inner core layer therebetween.

The present disclosure further relates to a method for preventing warpage in a semiconductor package. The method may include forming a semiconductor package substrate including an inner core layer. The method may include forming and arranging one or more channels longitudinally in the inner core layer. The method may include providing a mount assembly including one or more mounts. The method may also include inserting the one or more mounts into corresponding channels of the semiconductor package substrate.

To more readily understand and put into practical effect the present disclosure, particular aspects will now be described by way of examples and not limitations, and with reference to the drawings. For the sake of brevity, duplicate descriptions of features and properties may be omitted.

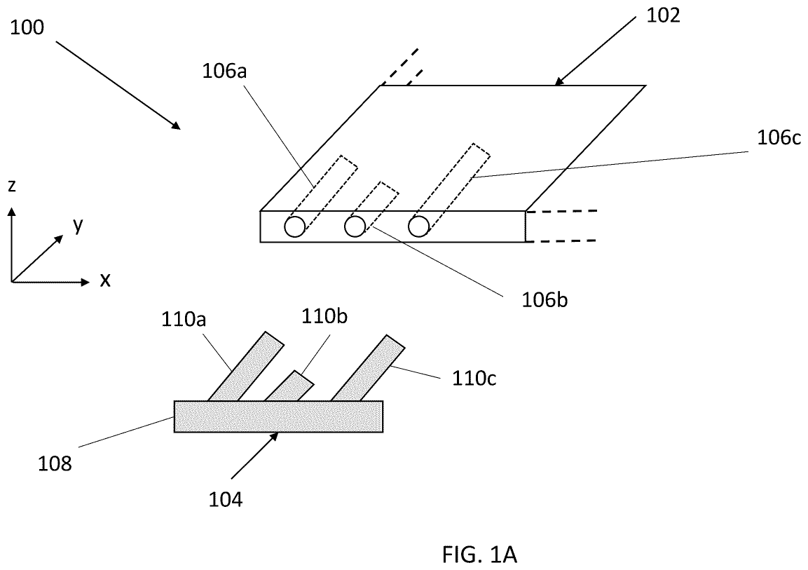

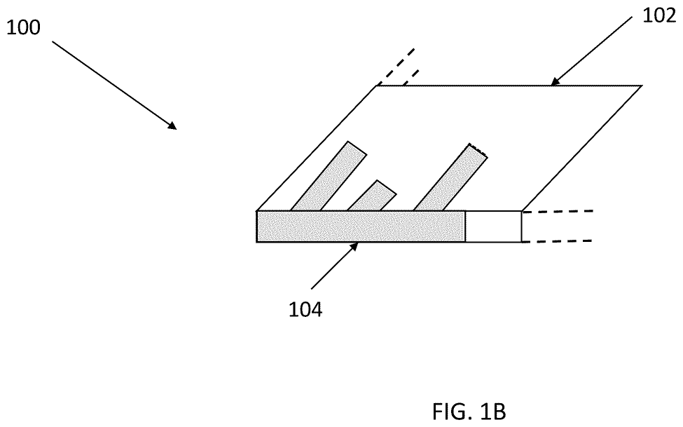

FIG. 1A shows a perspective view of an assembly 100 prior to an assembling of a panel 102 and an assembly mount 104 according to an aspect of the present disclosure. Additional electronic components, devices, or packages may be mounted or assembled onto the panel 102. Such additional electronic components, devices, or packages, as well as the manner of mounting or assembling, are commonly known in the field and thus, for the sake of discussion and brevity, the additional electronic components, devices, or packages, as well as the manner of mounting or assembling onto the panel 102 are omitted.

The panel 102 may take the form of a square (plan view), although other shapes such as a rectangle may also work. In the aspect shown in FIG. 1A, the shape of the panel 102 may be a square. Typical dimensions of the panel 102 may range from 300×300 mm² up to 650×650 mm², or even larger, depending on available panel technology. For simplicity, a panel in the present context may also refer to a semiconductor package.

The panel 102 may include one or more channels formed therein. In the aspect shown in FIG. 1A, a first channel 106a, a second channel 106b, and a third channel 106c may be formed in the panel.

The first channel 106a may be formed in-plane (i.e., longitudinally) in the panel 102, in the x-y plane. The first channel 106a may at least partially extend from a first side of the panel 102 to an opposing second side of the panel 102.

The second channel 106b may be formed in-plane in the panel 102, in the x-y plane. The second channel 106b may at least partially extend from a first side of the panel 102 to an opposing second side of the panel 102.

The third channel 106c may be formed in-plane in the panel 102, in the x-y plane. The third channel 106c may at least partially extend from a first side of the panel 102 to an opposing second side of the panel 102.

In the aspect shown in FIG. 1A, the first channel 106a, the second channel 106b, and the third channel 106c may extend at least partially from the same first side of the panel 102 to the same opposing second side of the panel 102.

The first channel 106a, the second channel 106b, and the third channel 106c may each extend in the y-axis direction to the same length or a different length in the panel 102. In the aspect shown in FIG. 1A, each of the first channel 106a, the second channel 106b, and the third channel 106c may extend in the y-axis direction to a different length. For example, the first channel 106a may extend longer than the second channel 106b but extend shorter than the third channel 106c in the y-axis direction.

The first channel 106a, the second channel 106b, and the third channel 106c may be parallel to one another in the y-axis direction.

In one aspect, the first channel 106a, the second channel 106b, and the third channel 106c may be spaced apart in an equal distance from one another in the x-axis direction. In another aspect, the first channel 106a, the second channel 106b, and the third channel 106c may be spaced apart in a varying distance from one another in the x-axis direction.

The assembly mount 104 may include a base 108. The assembly mount 104 may further include one or more mounts stemming from the base 108. In the aspect shown in FIG. 1A, a first mount 110a, a second mount 110b, and a third mount 110c may stem from the base 108 of the assembly mount 104. The first mount 110a, second mount 110b, and third mount 110c may be formed of a rigid material that may provide adequate stability to the package. However, if the mounts are meant to be later snipped off from base and left inside the package for thermal dissipation purpose, then these mounts should be metal based with significant thermal conductivity. Metals like copper may be a possible example.

Arrangement and configuration of the first mount 110a, the second mount 110b, and the third mount 110c may be dictated by the first channel 106a, the second channel 106b, and the third channel 106c, respectively, in the panel 102.

In various aspects, cross-sections of the first mount 110a, the second mount 110b, and the third mount 110c may correspond to the cross-sections of the first channel 106a, the second channel 106b, and the third channel 106c, respectively. For example, the cross-section of the first channel 106a and the cross-section of the first mount 110a may be a square, rectangle, circle, oval, triangle, etc. Further, the cross-section of the first mount 110a may not be larger than the cross-section of the first channel 106a such that the first mount 110a may be insertable into the first channel 106a. The same consideration may apply to the second channel 106b and the second mount 110b, as well as to the third channel 106c and the third mount 110c.

In other aspects, the cross-sections of the first mount 110a, the second mount 110b, and the third mount 110c may not correspond to the cross-sections of the first channel 106a, the second channel 106b, and the third channel 106c, respectively. In one example, the cross-section of the first channel 106a may be a square while the cross-section of the first mount 110a may be a circle. However, the cross-section of the first mount 110a may not be larger than the cross-section of the first channel 106a such that the first mount 110a may be insertable into the first channel 106a. The same consideration may apply to the second channel 106b and the second mount 110b, as well as to the third channel 106c and the third mount 110c.

In the aspect shown in FIG. 1A, the first mount 110a may stem or extend from the base 108 in the y-axis direction and to the same length as, or shorter length than, the first channel 106a. The second mount 110b may stem or extend from the base 108 in the y-axis direction and to the same length as, or shorter length than, the second channel 106b. And the third mount 110c may stem or extend from the base 108 in the y-axis direction and to the same length as, or shorter length than, the third channel 106c. In other words, each of the first mount 110a, second mount 110b, and third mount 110c may have an adjustable length of extension independent of one another.

The spacing between the first mount 110a and the second mount 110b may correspond to the spacing between the first channel 106a and the second channel 106b. Likewise, the spacing between the second mount 110b and the third mount 110c may correspond to the spacing between the second channel 106b and the third channel 106c.

The first mount 110a, the second mount 110b, and the third mount 110c may be parallel to one another in the y-axis direction.

FIG. 1B shows a perspective view of the assembly 100 of FIG. 1A, during and/or after assembling of the panel 102 and the assembly mount 104 according to an aspect of the present disclosure.

The panel 102 may be held flat during assembly by the first, second, and third mounts 110a, 110b, 110c, plugged into the first, second, and third channels 106a, 106b, 106c, respectively. In one aspect, the first, second, and third mounts 110a, 110b, 110c, may be fully plugged or inserted into the first, second, and third channels 106a, 106b, 106c, respectively, thereby stabilizing the panel 102 to minimize warpage. The channels 106a, 106b, 106c may be reused in the panel or final product for cooling and/or power supply as described in later paragraphs.

The assembly of the panel 102 and the assembly mount 104 may resemble a conventional household electrical plug having pins inserted into an electrical socket. Such stabilization plugs may reduce assembly issues and increase yield and can be re-utilized in the panel or final product for improved cooling and power, which increases device performance.

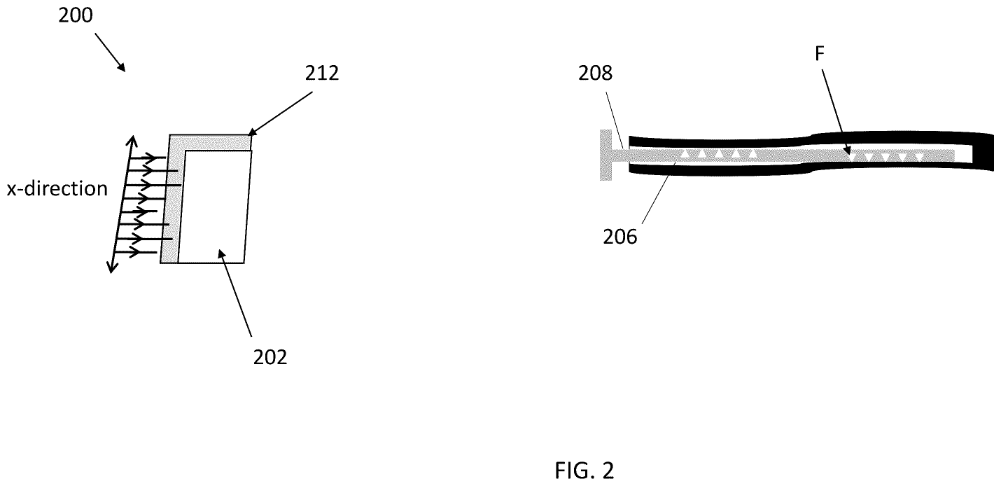

FIG. 2 shows a plan view (left) and a side view (right) of an assembly 200 of FIG. 1A, during and/or after assembling of a panel 202 and an assembly mount 204 according to an aspect of the present disclosure.

On assembly tool side, a set of adjustable mounts 208 may be provided around a part or the whole periphery of a chuck 212 (plan view). The adjustable mounts may be arranged in the x-axis direction as shown and each mount 208 may have an adjustment length. Once the panel 202 is placed on the assembly tool, the mounts 208 may be plugged into unfilled or partially filled part of the channels 206 to improve the stability during assembly as shown on the right view of FIG. 2. For simplicity, only one channel 206 and one mount 208 is illustrated. The rigidity of the mounts 208 may counteract warpage of the panel 202, as shown by forces F acting against the warpage direction.

After assembly on the panel 202 is complete, the mounts 208 may be withdrawn from the panel 202 by withdrawing the chuck 212 away from the panel 202 or optionally, the mounts 208 may be sacrificed by breaking them around the panel edge. Parts of the mounts 208 may then remain inside the channels 206 of the panel 202 for further stabilization and/or electrical/thermal conductivity improvement. In the latter cases, a good contact between the mounts 208 and channel fillers (not shown and will be described in later paragraphs) may be required. One option may be to use soft materials partially filling the outer parts of the channel 206, such that it may embed the mount 208 once inserted. It might also be possible to apply some heating in the outer channel area (e.g., via the mounts 208 themselves or by touch down of a ring heating plate), or other methods, in order to form/improve contact between the mounts 208 and the channel filler materials. Suitable soft filler materials may be any filler materials with low viscosity, such as a polymer-based filler material.

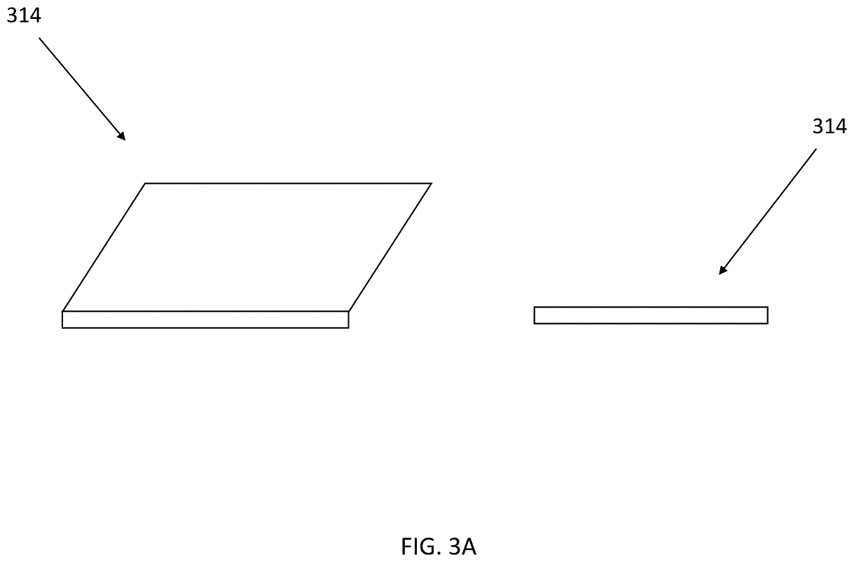

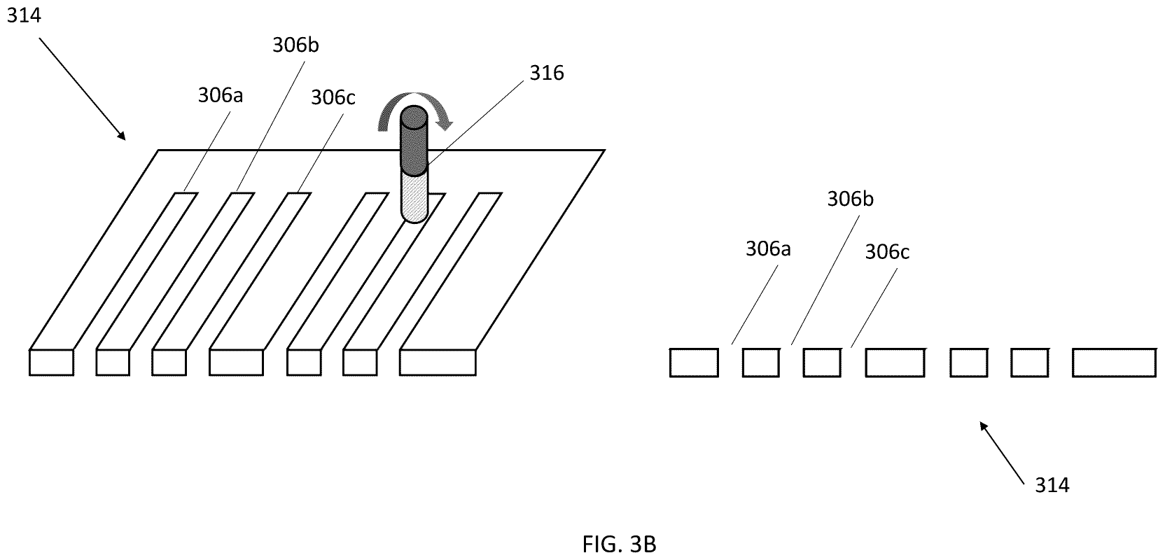

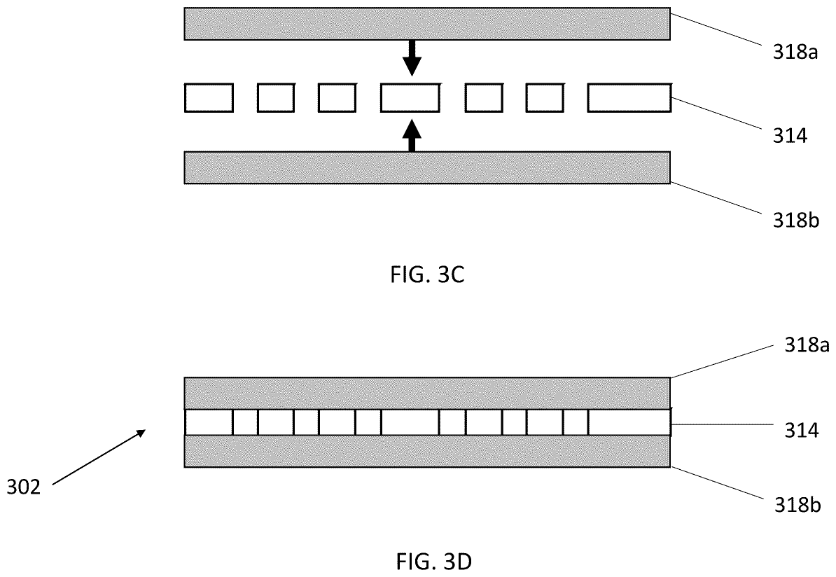

FIGS. 3A-3D show the formation of channels 306a, 306b, 306c in a panel 302 according to an aspect of the present disclosure.

FIG. 3A shows a perspective view (left) and a cross-sectional view (right), respectively, of an innermost core layer 314 of a panel 302. In one aspect, the innermost core layer 314 may include a glass reinforced epoxy core. In another aspect, the innermost core layer 314 may include a glass core.

FIG. 3B shows a perspective view (left) and a cross-sectional view (right), respectively, of the innermost core layer 314 after formation of channels 306a, 306b, 306c. The channels 306a, 306b, 306c in the innermost core layer 314 may be formed or manufactured by mechanical or laser cutting of the innermost core layer 314 before lamination of additional layers. In FIG. 3B, the channels 306a, 306b, 306c, which may be of the same or different sizes and directions, may be cut through the full thickness of the innermost core layer 314 by using a router or laser 316 for mechanical or laser cutting, respectively.

FIG. 3C shows the addition of additional layers 318a, 318b to the innermost core layer 314. In one aspect where the innermost core layer 314 may be a glass reinforced epoxy material, the additional layers 318a, 318b and the innermost core layer 314 may be laminated together such that the innermost core layer 314 may be sandwiched between the additional layers 318a, 318b. The arrows show the direction of applied force for the lamination.

In another aspect where the innermost core layer 314 may be a glass material, the additional layers 318a, 318b and the innermost core layer 314 may be thermally compressed together such that the innermost core layer 314 may be sandwiched between the additional layers 318a, 318b. The arrows show the direction of applied force for the thermal compression.

Two or more additional layers may be used to sandwich the innermost core layer 314. The additional layers 318a, 318b may include the same or a different material. For example, the additional layers 318a, 318b may be standard substrate materials used in the industry, i.e., any dielectric or prepreg materials could be used. The additional layers may be used as substrate buildup layers, or substrate core. The purpose of such additional layers is similar to that for any semiconductor package, such as for transmitting electrical signals between semiconductors and printed circuit boards.

FIG. 3D shows a completed full thickness core at panel level, i.e., the panel 302 having channels therein. Examples of a full thickness of inner core could range anywhere from about 100 μm to more than 1 mm. The depth may depend on the package size and may be normally larger than 1 mm.

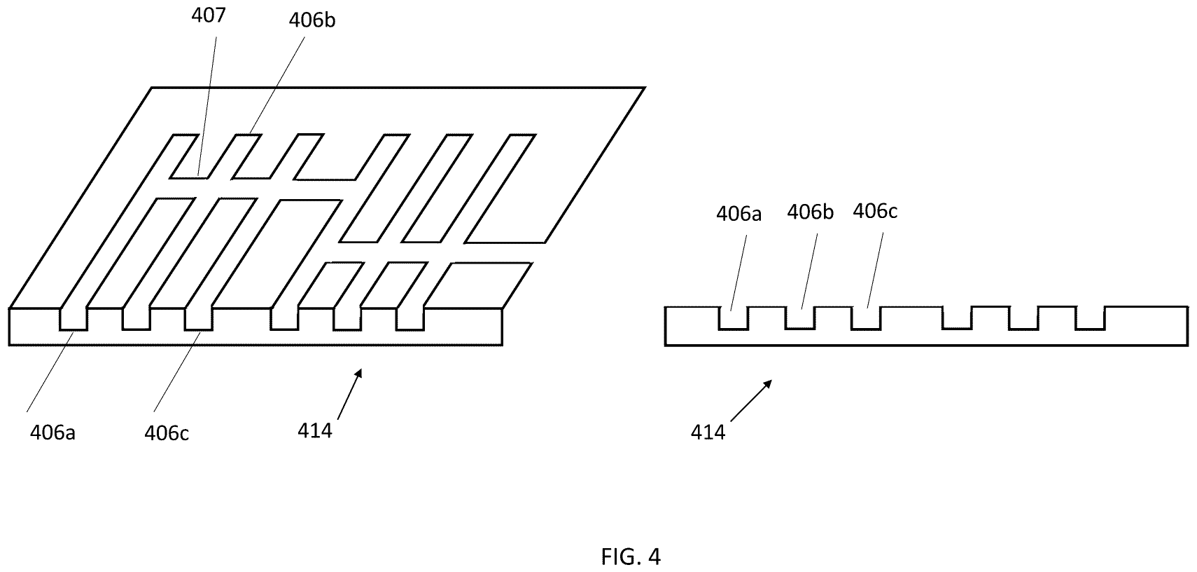

FIG. 4 shows a perspective view (left) and a cross-sectional view (right) of an innermost core layer 414 according to an aspect of the present disclosure. Different from the aspect illustrated in FIGS. 3A-3D, the cutting of channels 406a, 406b, 406c may not reach through the full thickness of the innermost core layer 414. This may allow more complex channel patterns to be formed without the innermost core layer 414 falling apart. Sub-channels 407 may also be formed in a similar manner as the channels 406a, 406b, 406c. The sub-channels 407 may be formed to connect two adjacent channels 406a, 406b.

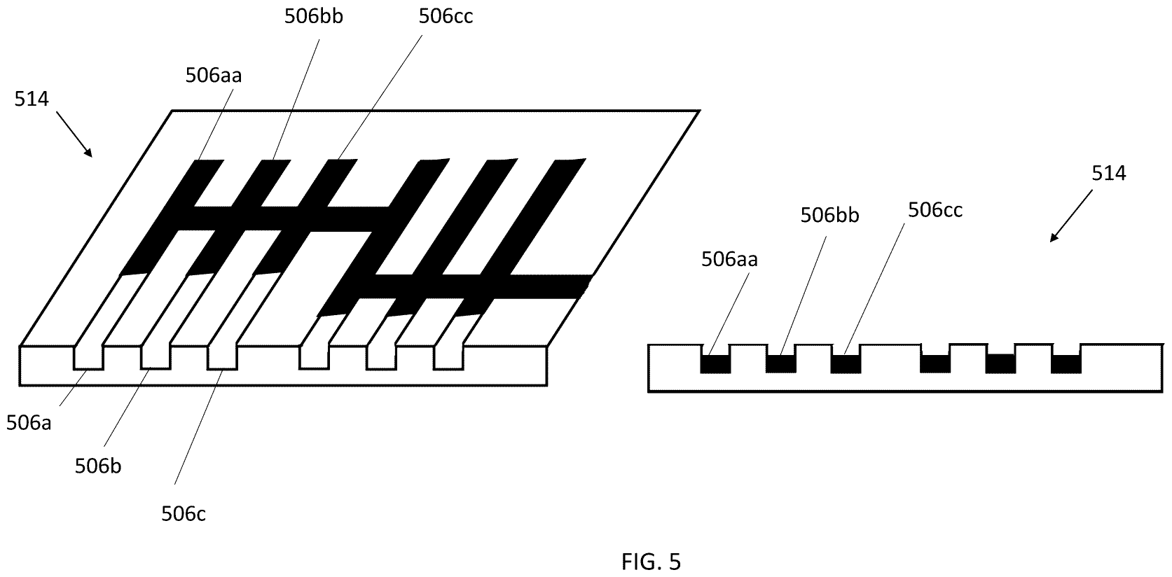

FIG. 5 shows a perspective view (left) and a cross-sectional view (right) of an innermost core layer 514 having partially filled channels 506aa, 506bb, 506cc according to an aspect of the present disclosure. In this aspect, the channels 506a, 506b, 506c may be partially filled with a channel filler material prior to the addition of additional layers as described above. Alternatively, the channels 506a, 506b, 506c may be completely filled (not shown) with a channel filler material prior to the addition of additional layers.

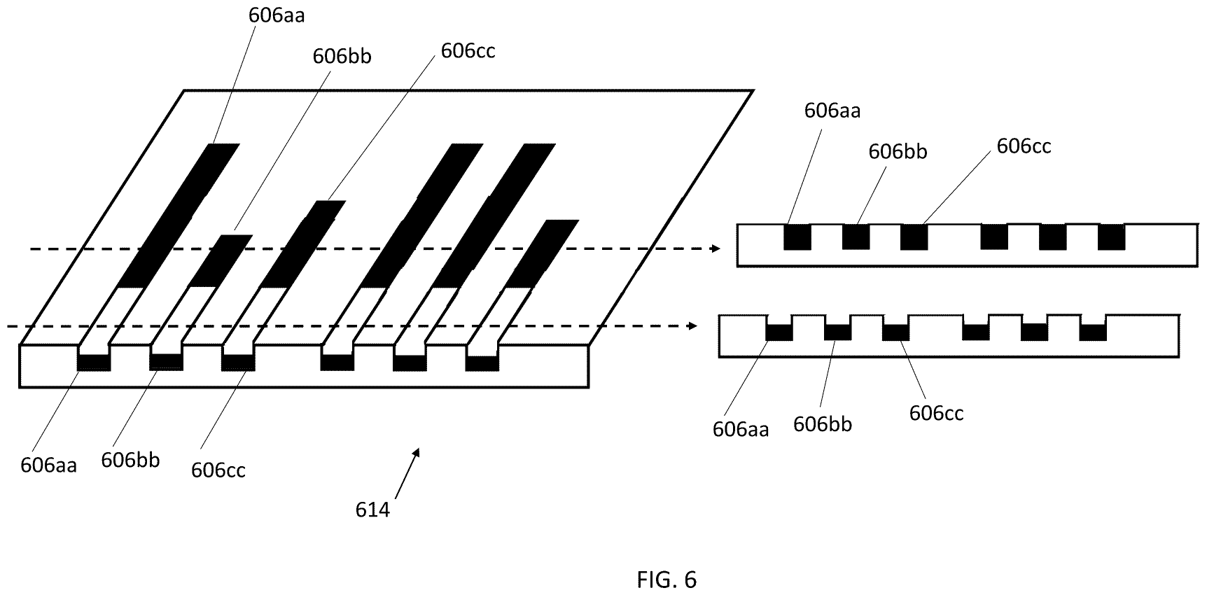

FIG. 6 shows a perspective view (left) and cross-sectional views (right) of an innermost core layer 614 having filled channels 606aa, 606bb, 606cc according to another aspect of the present disclosure. The cross-sectional views are taken along the line indicated by the respective broken arrow line. It can be clearly seen that the outer part of the channels (i.e., at the panel edge) may be partially filled while the inner part of the channels (i.e., away from the panel edge) may be completely filled.

In case of an organic core material such as a glass reinforced epoxy material, methods for the complete or partial filling of channels may include screen printing with a solder paste, plating with copper, polymer filling, or other low temperature processes to add a conductive or rigid component.

On the other hand, in case of a glass core material, higher temperature processing methods may also be possible, such as aluminum compression molding, to fill the channels.

Unfilled or partially filled channels may be re-used in the final panel or product for liquid or vapor cooling. As an example, partial filling may include some coating to seal the channels.

Complete or partial filling of the channels may serve one or more purposes, including:
Increasing stability or flexibility in dedicated parts of the panel: Channel structure could be pre-calculated to compensate expected warpage
Formation of electrically and/or thermally conductive paths
Making electrical and/or thermal connections between conductive structures in the outer layers: At various positions inside the channels, electrically or thermally conductive structures in the outer layers may be exposed to the channels for forming contact with channel filler material.

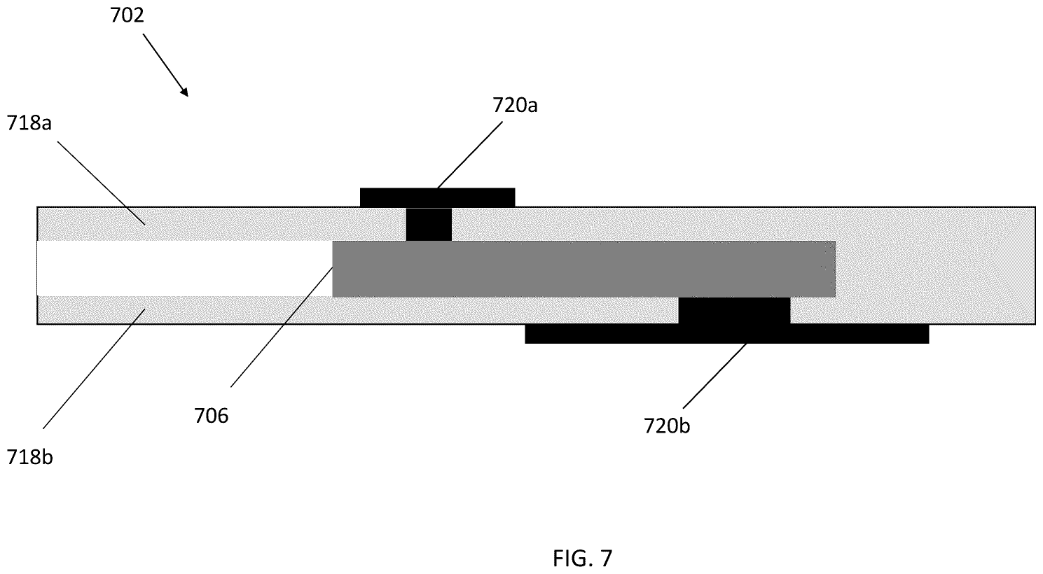

FIG. 7 shows a side view of electrical and/or thermal connections between conductive structures 720a, 720b in a panel 702 according to an aspect of the present disclosure.

In FIG. 7, the panel 702 may include an innermost core layer sandwiched between two additional layers 718a, 718b as described above. A partially filled channel 706 containing a conductive filler material may be formed therein. Openings or vias may be formed on each of the additional layers 718a, 718b to accommodate a respective conductive structure 720a, 720b. The conductive structures 720a, 720b and the conductive filler material may provide an electrical and/or thermal pathway between external components or devices (not shown) coupled to the respective conductive structures 720a, 720b.

Suitable materials for the conductive structures 720a, 720b may include copper or any similar metals with good thermal and/or electrical properties.

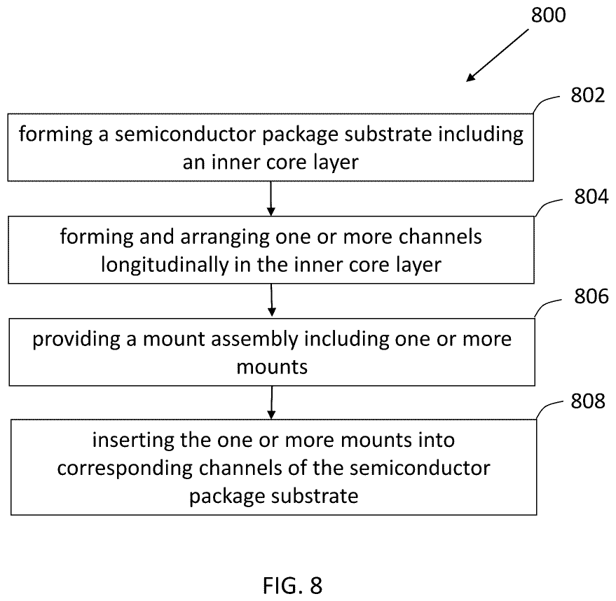

FIG. 8 shows a flow chart illustrating a method 800 for preventing warpage in a panel according to an aspect of the present disclosure.

At operation 802, the method 800 may include forming a semiconductor package substrate including an inner core layer.

At operation 804, the method 800 may also include forming and arranging one or more channels longitudinally in the inner core layer.

At operation 806, the method 800 may also include providing a mount assembly including one or more mounts.

At operation 808, the method 800 may also include inserting the one or more mounts into corresponding channels of the semiconductor package substrate.

### Examples

Example 1 may include an assembly. The assembly may include a semiconductor package substrate including one or more channels arranged longitudinally in an inner core layer of the semiconductor package substrate, and a mount assembly including one or more mounts operable to be insertable into corresponding channels of the semiconductor package substrate.

Example 2 may include the assembly of example 1 and/or any other example disclosed herein, wherein the mount assembly may include a base from which the one or more mounts extend, wherein each of the one or more mounts has an adjustable length of extension.

Example 3 may include the assembly of example 2 and/or any other example disclosed herein, wherein each of the one or more mounts may have a different length of extension.

Example 4 may include the assembly of example 1 and/or any other example disclosed herein, wherein the one or more mounts may be detachable from the mount assembly after insertion into the channels of the semiconductor package substrate.

Example 5 may include the assembly of example 1 and/or any other example disclosed herein, further including a chuck operable to receive the semiconductor package substrate.

Example 6 may include the assembly of example 5 and/or any other example disclosed herein, wherein the mount assembly may form a part of the chuck.

Example 7 may include a semiconductor package substrate. The semiconductor package substrate may include an inner core layer including one or more channels arranged longitudinally in the inner core layer, wherein each of the one or more channels may have an opening extending from one side of the inner core layer, and two outer layers arranged to sandwich the inner core layer therebetween.

Example 8 may include the semiconductor package substrate of example 7 and/or any other example disclosed herein, wherein each of the one or more channels may have a different length of extension from one side of the inner core layer.

Example 9 may include the semiconductor package substrate of example 7 and/or any other example disclosed herein, wherein the inner core layer may include a glass or a glass reinforced epoxy material.

Example 10 may include the semiconductor package substrate of example 7 and/or any other example disclosed herein, wherein the one or more channels may be arranged in parallel to one another.

Example 11 may include the semiconductor package substrate of example 7 and/or any other example disclosed herein, further including one or more sub-channels arranged non-longitudinally in the inner core layer to connect two or more channels.

Example 12 may include the semiconductor package substrate of example 7 and/or any other example disclosed herein, further including a channel filler material in the one or more channels.

Example 13 may include the semiconductor package substrate of example 12 and/or any other example disclosed herein, wherein the channel filler material may include a conductive material, a polymer, or a rigid component.

Example 14 may include the semiconductor package substrate of example 12 and/or any other example disclosed herein, wherein two outer layers each may include an opening operable to accommodate a conductive structure.

Example 15 may include the semiconductor package substrate of example 14 and/or any other example disclosed herein, wherein the conductive structure may be in contact with the channel filler material.

Example 16 may include a method. The method may include forming a semiconductor package substrate including an inner core layer. The method may include forming and arranging one or more channels longitudinally in the inner core layer. The method may include providing a mount assembly including one or more mounts. The method may also include inserting the one or more mounts into corresponding channels of the semiconductor package substrate.

Example 17 may include the method of example 16 and/or any other example disclosed herein, wherein forming the one or more channels may include cutting the inner core layer by a router or a laser.

Example 18 may include the method of example 16 and/or any other example disclosed herein, wherein the one or more mounts may be rigid.

Example 19 may include the method of example 16 and/or any other example disclosed herein, wherein a length of each of the one or more mounts may correspond to a length of each of the corresponding one or more channels.

Example 20 may include the method of example 16 and/or any other example disclosed herein, further including detaching the one or more mounts from the mount assembly after inserting the one or more mounts into corresponding channels.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. An assembly, the assembly comprising:
a semiconductor package substrate comprising one or more channels arranged longitudinally in an inner core layer of the semiconductor package substrate; and
a mount assembly comprising one or more mounts operable to be insertable into corresponding channels of the semiconductor package substrate.

2. The assembly of claim 1, wherein the mount assembly comprises a base from which the one or more mounts extend, wherein each of the one or more mounts has an adjustable length of extension.

3. The assembly of claim 2, wherein each of the one or more mounts has a different length of extension.

4. The assembly of claim 1, wherein the one or more mounts are detachable from the mount assembly after insertion into the channels of the semiconductor package substrate.

5. The assembly of claim 1, further comprising a chuck operable to receive the semiconductor package substrate.

6. The assembly of claim 5, wherein the mount assembly forms a part of the chuck.

7. A semiconductor package substrate comprising:
an inner core layer comprising one or more channels arranged longitudinally in the inner core layer, wherein each of the one or more channels has an opening extending from one side of the inner core layer; and
two outer layers arranged to sandwich the inner core layer therebetween.

8. The semiconductor package substrate of claim 7, wherein each of the one or more channels has a different length of extension from one side of the inner core layer.

9. The semiconductor package substrate of claim 7, wherein the inner core layer comprises a glass or a glass reinforced epoxy material.

10. The semiconductor package substrate of claim 7, wherein the one or more channels are arranged in parallel to one another.

11. The semiconductor package substrate of claim 7, further comprising one or more sub-channels arranged non-longitudinally in the inner core layer to connect two or more channels.

12. The semiconductor package substrate of claim 7, further comprising a channel filler material in the one or more channels.

13. The semiconductor package substrate of claim 12, wherein the channel filler material comprises a conductive material, a polymer, or a rigid component.

14. The semiconductor package substrate of claim 12, wherein the two outer layers each comprises an opening operable to accommodate a conductive structure.

15. The semiconductor package substrate of claim 14, wherein the conductive structure is in contact with the channel filler material.

16. A method, the method comprising:
forming a semiconductor package substrate comprising an inner core layer;
forming and arranging one or more channels longitudinally in the inner core layer;
providing a mount assembly comprising one or more mounts; and
inserting the one or more mounts into corresponding channels of the semiconductor package substrate.

17. The method of claim 16, wherein forming the one or more channels comprises cutting the inner core layer by a router or a laser.

18. The method of claim 16, wherein the one or more mounts are rigid.

19. The method of claim 16, wherein a length of each of the one or more mounts corresponds to a length of each of the corresponding one or more channels.

20. The method of claim 16, further comprising detaching the one or more mounts from the mount assembly after inserting the one or more mounts into corresponding channels.
